(19) United States
(12) Patent Application Publication
(10) Pub. No.: US 2023/0384232 A1
(43) Pub. Date: Nov. 30, 2023

(54) OPTICAL SENSOR

(71) Applicant: BROTHER KOGYO KABUSHIKI KAISHA, Nagoya (JP)

(72) Inventor: Mikio Inuzuka, Okazaki (JP)

(73) Assignee: BROTHER KOGYO KABUSHIKI KAISHA, Nagoya (JP)

(21) Appl. No.: 18/311,273

(22) Filed: May 3, 2023

(30) Foreign Application Priority Data
May 25, 2022 (JP) 2022-085354
May 25, 2022 (JP) 2022-085355

(51) Int. Cl. G01N 21/86; G03G 15/00

(52) U.S. Cl. CPC G01N 21/86; G03G 15/556

(57) ABSTRACT

An optical sensor configured to detect a sensing object includes a plate-shaped substrate, a light-emitting element, and a first light-receptive element. The plate-shaped substrate has a front surface, a back surface and a first hole piercing through the front surface and the back surface. The light-emitting element emits light and is fixed to the substrate. The first light-receptive element receives reflected light emitted from the light-emitting element, reflected off the sensing object and traveling into the first hole. The first light-receptive element is fixed to the back surface of the substrate. The first hole extends from a position at which the first light-receptive element is fixed toward a position at which the light-emitting element is fixed.

### REFERENCE TO RELATED APPLICATIONS

This application claims priority from Japanese Patent Application Nos. 2022-085354 and 2022-085355 filed on May 25, 2022. The entire contents of the priority applications are incorporated herein by reference.

### BACKGROUND ART

An optical sensor for measuring a position and density of a toner image (patch) formed on a belt in an image forming apparatus is known in the art. The optical sensor is located opposite to the belt, and includes one light-emitting element and two light-receptive elements. The light-emitting element and the light-receptive elements are soldered to a substrate.

### DESCRIPTION

In order to reduce the thickness of an optical sensor, it is conceivable to locate a light-receptive element on a back surface of a substrate. In this case, it is necessary to provide a through hole in the substrate for allowing light to travel therethrough to be received by the light-receptive element. However, part of light to be received by the light-receptive element may be interrupted by an edge of the through hole when traveling into the through hole with the result that quantity of the light would disadvantageously be reduced.

It would be desirable to restrain undesirable reduction in quantity of light travelling into the through hole to be received by the light-receptive element of the optical sensor.

Thus, in one aspect, an optical sensor disclosed herein configured to detect a sensing object comprises a plate-shaped substrate, a light-emitting element, and a first light-receptive element. The plate-shaped substrate has a front surface, a back surface and a first hole piercing through the front surface and the back surface. The light-emitting element emits light and is fixed to the substrate. The first light-receptive element receives reflected light emitted from the light-emitting element, reflected off the sensing object and traveling into the first hole. The first light-receptive element is fixed to the back surface of the substrate. The first hole extends from a position at which the first light-receptive element is fixed toward a position at which the light-emitting element is fixed.

According to this configuration, since the first hole of the substrate extends from a position at which the first light-receptive element is fixed toward a position at which the light-emitting element is fixed, light to be received by the first light-receptive element is less likely to be interrupted by an edge of the first hole. Accordingly, undesirable reduction in quantity of light traveling into the first hole to be received by the first light-receptive element can be restrained.

The above-described optical sensor may be configured such that the substrate further has a second hole piercing through the front surface and the back surface, the optical sensor further comprises a second light-receptive element that receives a diffuse reflection component of light reflected off the sensing object and traveling into the second hole and is fixed to the back surface of the substrate, and the second hole extends from a position at which the second light-receptive element is fixed toward the position at which the light-emitting element is fixed.

The above-described optical sensor may further comprise a holder by which the substrate is held. The holder may comprise an emitted-light path hole through which light emitted from the light-emitting element travels, a first reflected-light path hole through which light reflected off the sensing object travels to the first light-receptive element, and a second reflected-light path hole through which light reflected off the sensing object travels to the second light-receptive element.

The above-described optical sensor may be configured such that the holder further comprises a first light-shielding wall located between the light-emitting element and the first light-receptive element, and a second light-shielding wall located between the light-emitting element and the second light-receptive element, wherein the first light-shielding wall has a groove formed in a surface thereof facing to the light-emitting element.

According to this configuration, light emitted from the light-emitting element can be restrained by the first light-shielding wall from directly reaching the first light-receptive element and restrained by the second light-shielding wall from directly reaching the second light-receptive element. Further, since the first light-shielding wall has a groove formed in a surface thereof facing to the light-emitting element, light reflected off the first light-shielding wall can be restrained from reaching the second light-receptive element. As a result, the second light-receptive element can provide an improved readout with high accuracy and precision.

The above-described optical sensor may be configured such that the groove extends parallel to an optical axis of the light-emitting element.

The above-described optical sensor may be configured such that the first hole has a first portion through which a specular reflection component of light reflected off the sensing object travels, and a second portion connected to the first portion and extending in a direction nonparallel to a direction of extension of the first portion, and the second hole has a third portion through which a diffuse reflection component of the light reflected off the sensing object travels, and a fourth portion connected to the third portion and extending in a direction nonparallel to a direction of extension of the third portion, wherein the first light-shielding wall includes a first leg disposed in the second portion, and wherein the second light-shielding wall includes a second leg disposed in the fourth portion.

The above-described optical sensor may be configured such that the light-emitting element is fixed to the back surface of the substrate, and the substrate has a third hole that is a through hole piercing through the front surface and the back surface, through which light emitted from the light-emitting element travels.

According to this configuration, since the light-emitting element and the light-receptive elements are fixed to the back side of the substrate, the optical sensor can be assembled with increased ease.

The above-described optical sensor may further comprise a holder for holding the substrate. The holder may comprise an emitted-light path hole through which light emitted from the light-emitting element travels, and a first reflected-light path hole through which light reflected off the sensing object travels to the first light-receptive element.

The above-described optical sensor may be configured such that the holder further comprises a first light-shielding wall located between the light-emitting element and the first light-receptive element, wherein the first light-shielding wall has a groove formed in a surface thereof facing to the light-emitting element.

The above-described optical sensor may be configured such that the first hole has a first portion through which a specular reflection component of light reflected off the sensing object travels, and a second portion connected to the first portion and extending in a direction nonparallel to a direction of extension of the first portion, wherein the first light-shielding wall includes a first leg disposed in the second portion.

Further to the above, accuracy and precision in readouts of an optical sensor may decrease when there is a large error in distances from a light-emitting element, a light-receptive element and a lens member to a patch. Thus, it would be desirable to reduce such error in distances from the light-emitting element, the light-receptive element and the lens member to the patch.

In another aspect, an optical sensor disclosed herein to be attached to a frame of an image forming apparatus and configured to detect a sensing object comprises a substrate, a light-emitting element, a light-receptive element, a holder and a lens member. The light-emitting element emits light and is fixed to the substrate. The light-receptive element receives reflected light emitted from the light-emitting element and reflected off the sensing object and is fixed to the substrate. The holder comprises a holder body and a first hook protruding from the holder body. The first hook is engageable with the frame. The lens member is located between the frame and the substrate and has an optical surface through which light emitted from the light-emitting element travels. When the first hook is engaged with the frame, the holder body presses the lens member against the frame.

According to this configuration, when the first hook is engaged with the frame, the holder body presses the lens member against the frame. The lens member can thereby be pressed against and fixed to the frame. As a result, an error in distances from the light-emitting element, the light-receptive element, and the lens member to the patch can be minimized.

The above-described optical sensor may be configured to further comprise a substrate retainer by which the substrate is held and fixed between the holder and the substrate retainer. The substrate retainer may be configured to comprise a retainer body and a second hook protruding from the retainer body and engageable with the holder, wherein when the second hook is engaged with the holder, the retainer body presses the substrate against the holder.

According to this configuration, when the second hook is engaged with the holder, the retainer body presses the substrate against the holder. The substrate can thereby be pressed against and fixed to the holder. As a result, an error in distances from the light-emitting element, the light-receptive element, and the lens member to the patch can be minimized.

The above-described optical sensor may be configured such that the holder further comprises a locating protrusion configured such that when the lens member is attached to the holder, the locating protrusion protruding toward the lens member contacts the lens member.

According to this configuration, since the lens member is located in place relative to the holder by the locating protrusion, a high positioning accuracy of the lens member can be achieved.

The above-described optical sensor may be configured such that the lens member comprises a protrusion configured such that when the optical sensor is attached to the frame, the protrusion protruding toward the frame contacts the frame, and the optical surface is kept out of contact with the frame.

According to this configuration, the protrusion in contact with the frame serves to restrain the optical surface from being displaced relative to the frame, and the optical surface kept out of contact with the frame is restrained from suffering damage by the contact.

The above-described optical sensor may be configured such that the lens member further comprises a third hook engageable with the holder.

According to this configuration, the lens member is rendered less likely to be detached from the holder.

The above-described optical sensor may be configured such that the substrate is a plate-shaped member extending in a lengthwise direction, and the third hook is configured such that when the lens member is attached to the holder, the third hook extends into the holder. The third hook may have a hook hole that is a through hole piercing through the third hook in the lengthwise direction. The holder may be configured to further comprise a holder lug protruding in the lengthwise direction and engageable with the hook hole, wherein when the lens member is attached to the holder, a clearance is left between the hook hole and the holder lug engaged with the hook hole in a direction of thickness of the substrate.

According to this configuration, the holder lug engaged with the hook hole with a clearance in the third direction serves to keep the lens member from being detached from the holder, without obstructing proper positioning of the lens member on the holder. In addition, engagement of the holder lug with the hook hole serves to restrain the lens member from deforming.

The above-described optical sensor may be configured such that the light-receptive element comprises a first light-receptive element that receives a specular reflection component of light reflected off the sensing object, and a second light-receptive element that receives a diffuse reflection component of the light reflected off the sensing object, and the substrate comprises a first hole corresponding to the first light-receptive element, and a second hole corresponding to the second light-receptive element.

The above-described optical sensor may be configured such that the holder further comprises a first light-shielding wall located between the light-emitting element and the first light-receptive element, and a second light-shielding wall located between the light-emitting element and the second light-receptive element, and the first light-shielding wall has a groove formed in a surface thereof facing to the light-emitting element.

According to this configuration, light emitted from the light-emitting element can be restrained by the first light-shielding wall from directly reaching the first light-receptive element and restrained by the second light-shielding wall from directly reaching the second light-receptive element. Further, since the first light-shielding wall has a groove formed in a surface thereof facing to the light-emitting element, light reflected off the first light-shielding wall can be restrained from reaching the first light-receptive element and the second light-receptive element. As a result, the first light-receptive element and the second light-receptive element can provide an improved readout with high accuracy and precision.

The above-described optical sensor may be configured such that the groove extends parallel to an optical axis of the light-emitting element.

The above-described optical sensor may be configured such that the lens member is a lens having a positive power, and having a first surface facing to the frame and a second surface facing to the substrate, a radius of curvature of the first surface being larger than a radius of curvature of the second surface.

According to this configuration, since the radius of curvature of the second surface, which does not face the frame, is smaller than the radius of curvature of the first surface, the operation of attaching the optical sensor to the frame is unlikely to damage the lens member.

The above and other aspects, further features and advantages will become more apparent by describing in detail illustrative, non-limiting embodiments thereof with reference to the accompanying drawings, in which:

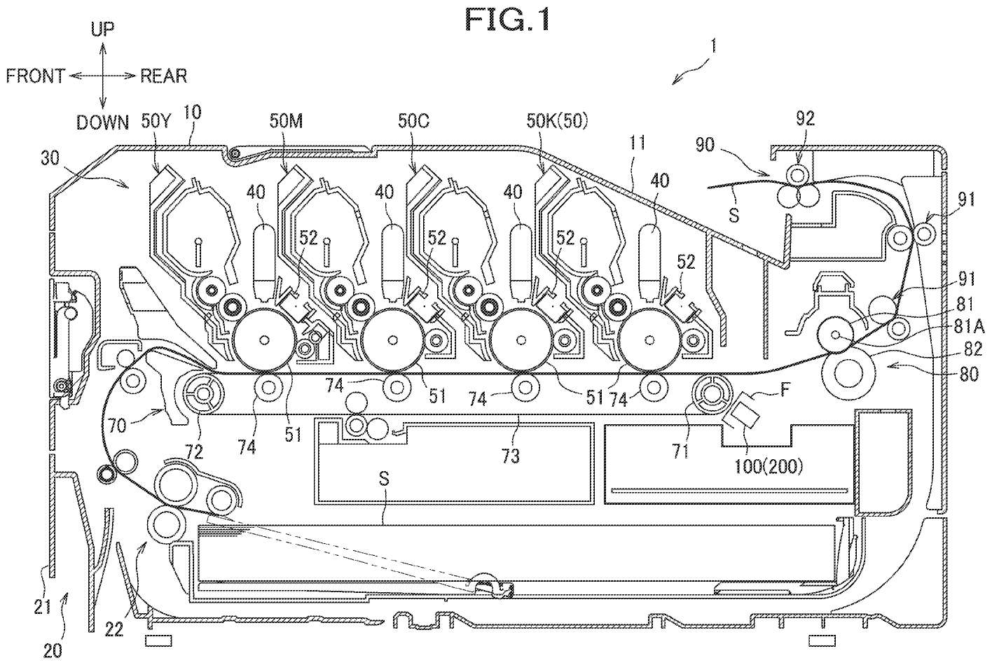

FIG. 1 is a section view of a multicolor printer.

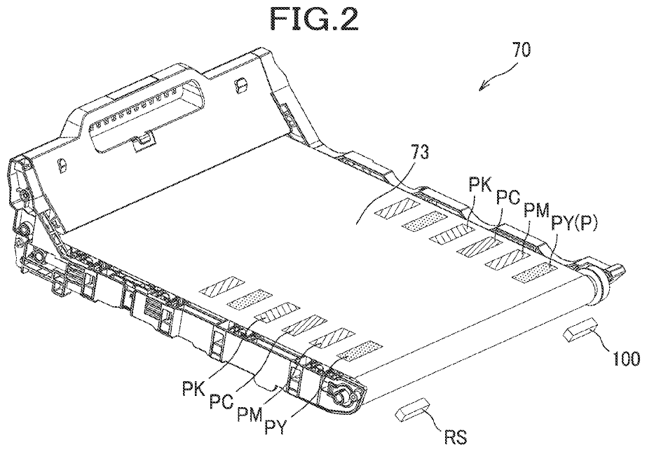

FIG. 2 is a perspective view illustrating a belt unit and an optical sensor.

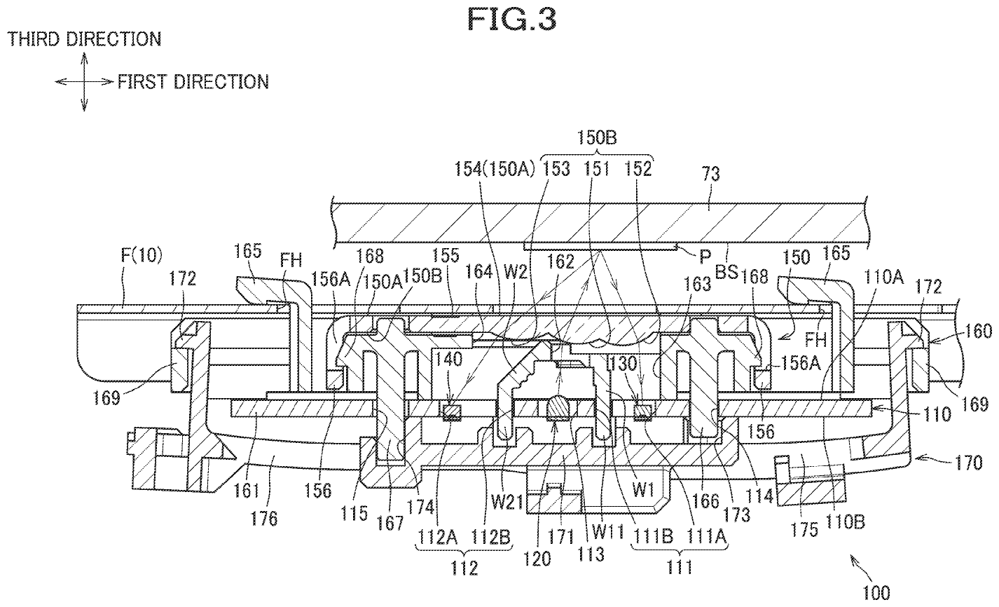

FIG. 3 is a section view of a first example of an optical sensor.

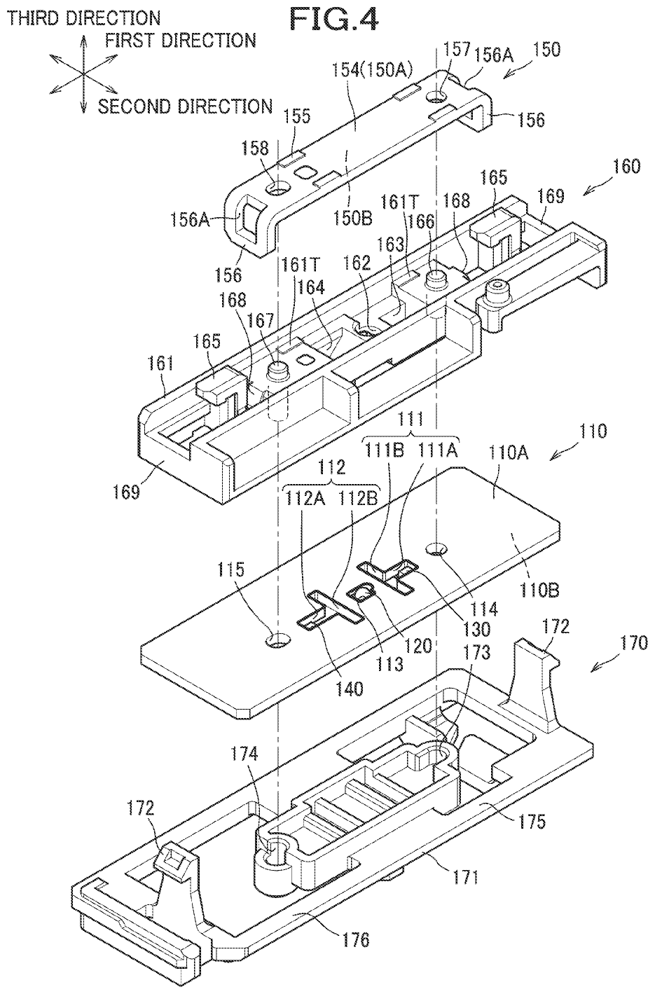

FIG. 4 is an exploded perspective view of the optical sensor of FIG. 3, illustrating sides of its components facing toward a frame.

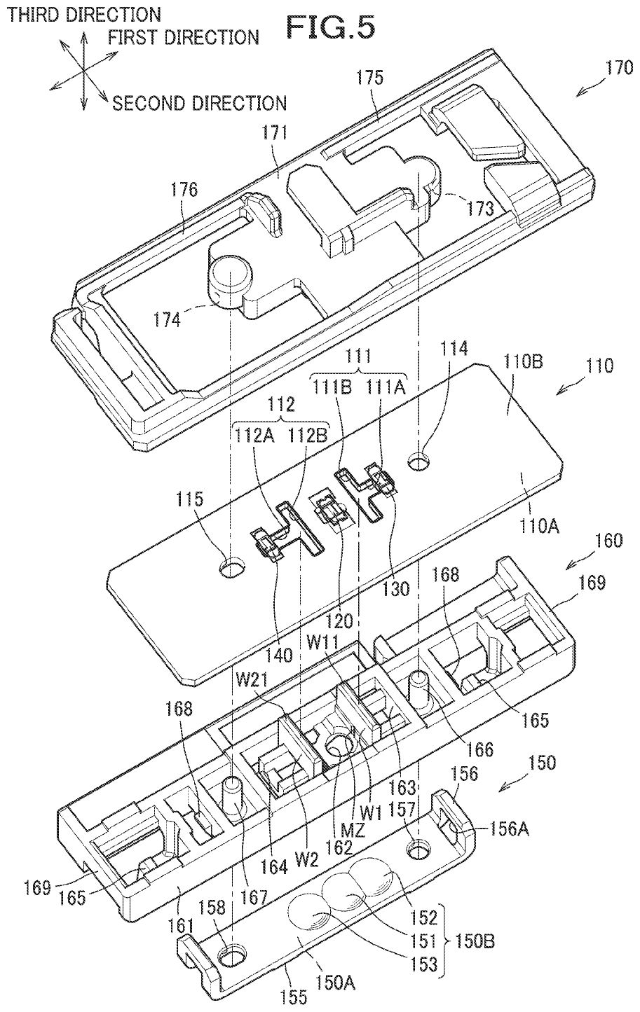

FIG. 5 is an exploded perspective view of the optical sensor of FIG. 3, illustrating sides of its components facing away from the frame.

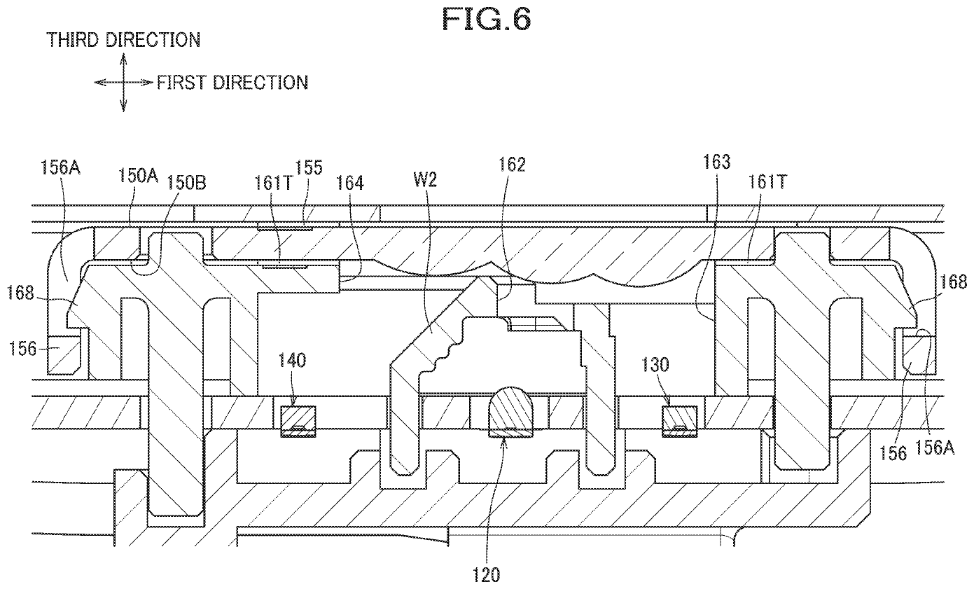

FIG. 6 is a partial enlarged view of the optical sensor shown in FIG. 3, for explaining contacted parts of a lens member and a holder.

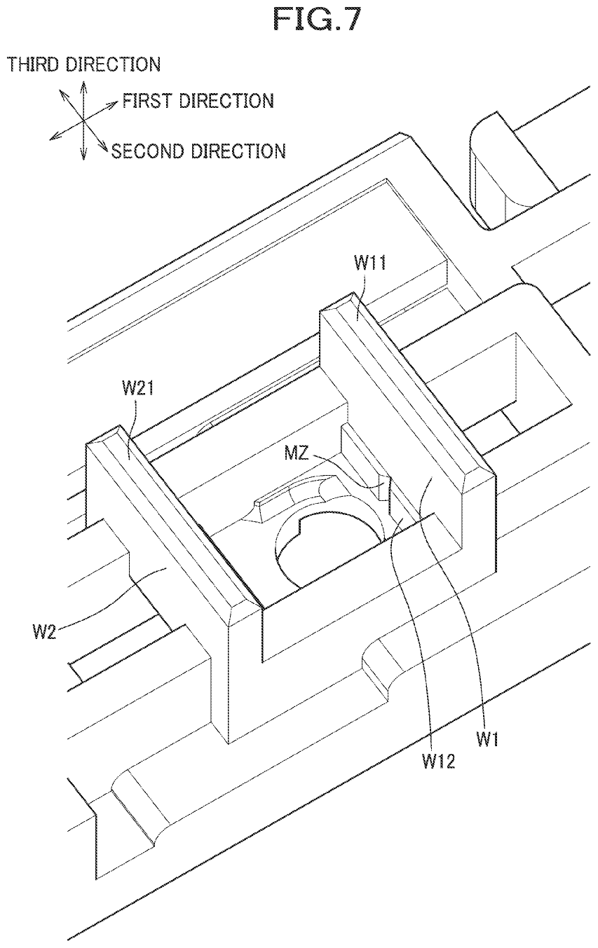

FIG. 7 is a partial enlarged view of the holder shown in FIG. 5, for explaining a groove formed in an opposite surface.

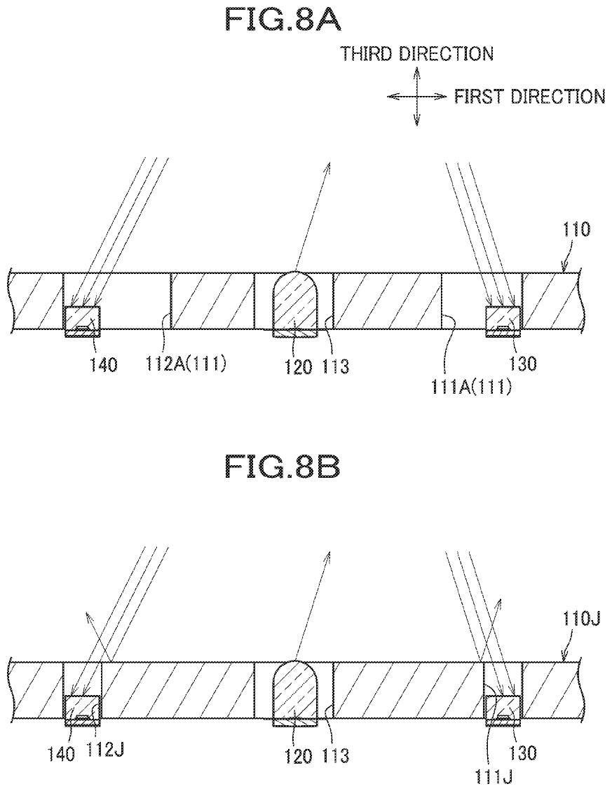

FIG. 8A is a schematic diagram showing a path of light received by a light-receptive element in the optical sensor shown in FIG. 3.

FIG. 8B is a schematic diagram showing a path of light received by a light-receptive element in an optical sensor having a configuration different from the optical sensor shown in FIG. 3.

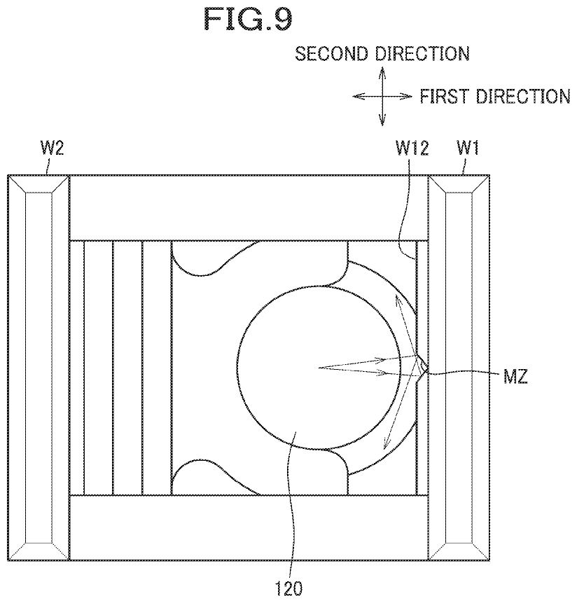

FIG. 9 is a schematic diagram showing an effect of the groove by which light emitted from a light-emitting element to the opposite surface is reflected off the groove.

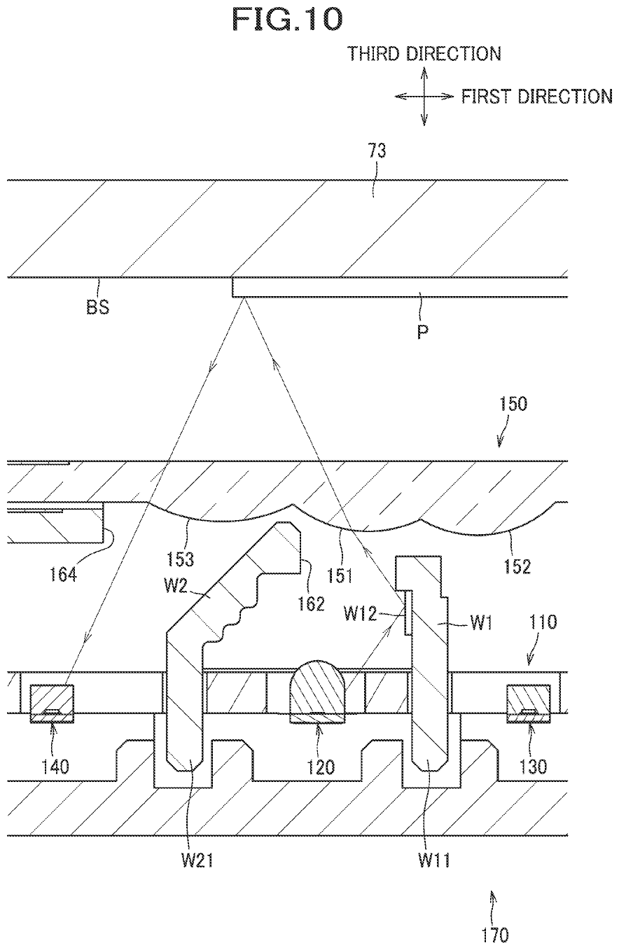

FIG. 10 is a schematic diagram showing an example of a path of light incident on an opposite surface having no groove formed therein.

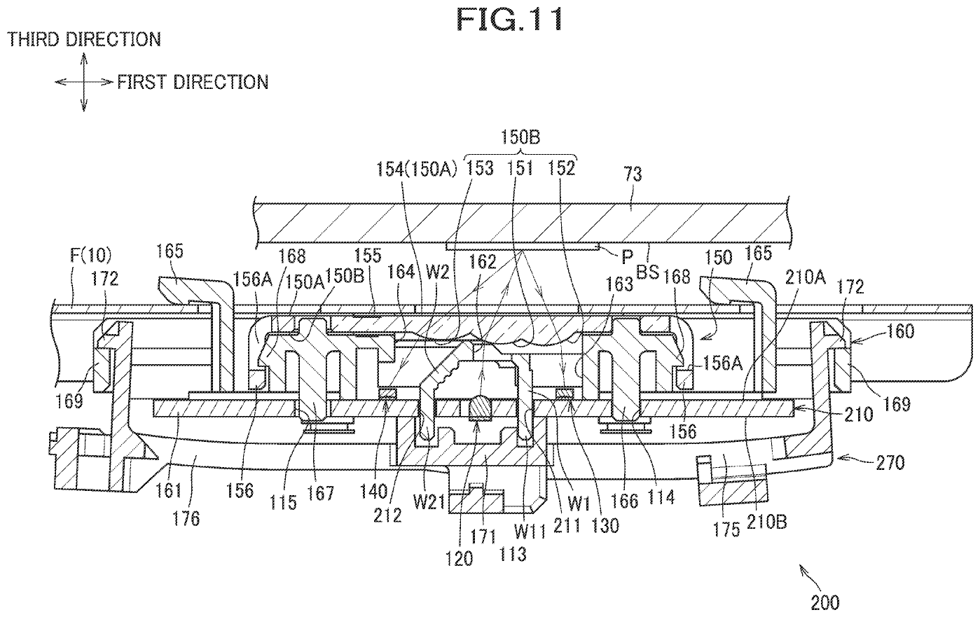

FIG. 11 a section view of a second example of the optical sensor.

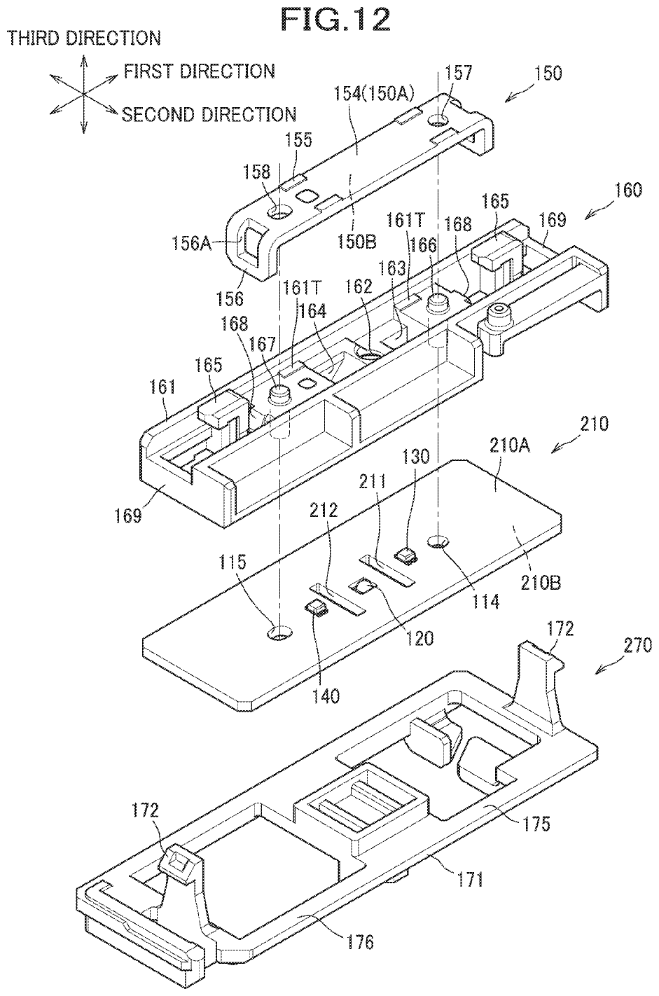

FIG. 12 is an exploded perspective view of the optical sensor of FIG. 11, illustrating sides of its components facing toward the frame.

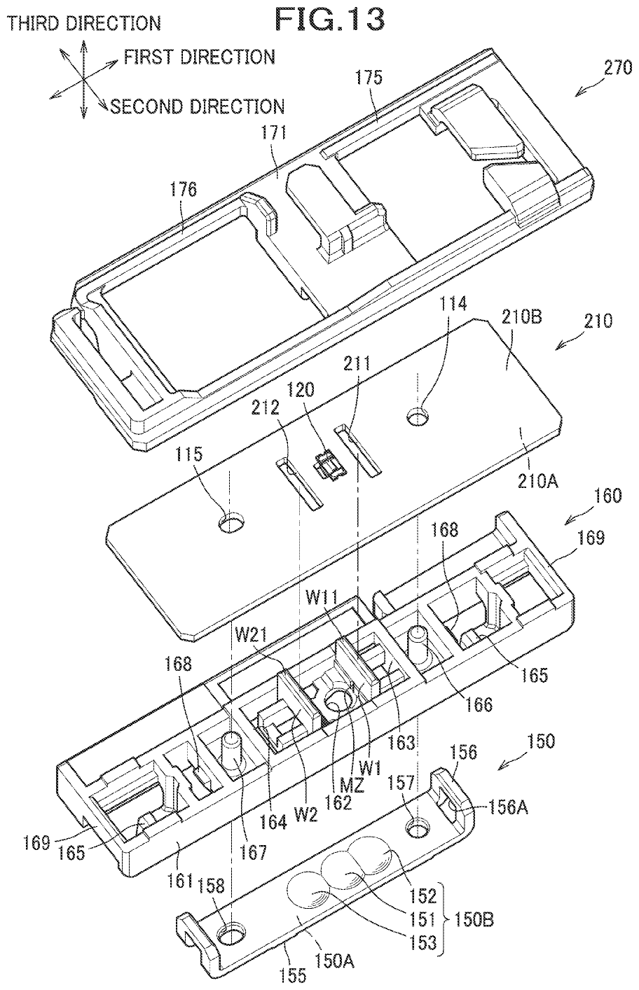

FIG. 13 is an exploded perspective view of the optical sensor of FIG. 11, illustrating sides of its components facing away from the frame.

Next, a detailed description will be given of an image forming apparatus and various examples of optical sensors with reference to the drawings.

As shown in FIG. 1, a laser printer 1 as an example of the image forming apparatus includes a main body housing 10, a feeder unit 20, an image forming unit 30, and a sheet output unit 90.

The feeder unit 20 includes a sheet feed tray 21 and a sheet feed device 22. The sheet feed tray 21 is a tray that holds sheets S. The sheet feed device 22 conveys a sheet S from the sheet feed tray 21 to the image forming unit 30.

The image forming unit 30 includes four LED units 40, four process cartridges 50, a belt unit 70, and a fixing device 80.

Each of the LED units 40 includes a plurality of light-emitting diodes (LEDs). The LED units 40 expose photosensitive drums 51, which will be described later, to light.

Each of the process cartridges 50 includes a photosensitive drum 51, and a charger 52, as well as a development roller and a toner container for which reference characters are omitted, and other components. The process cartridges 50 include a process cartridge 50K for toner of a black color, a process cartridge 50Y for toner of a yellow color, a process cartridge 50M for toner of a magenta color, and a process cartridge for toner of a cyan color. The process cartridges 50Y, 50M, 50C and 50K are arranged in this order in a direction of conveyance of a sheet S; i.e., the process cartridge 50M is located immediately downstream of the process cartridge 50Y, the process cartridge 50C is located immediately downstream of the process cartridge 50M, and the process cartridge 50K is located immediately downstream of the process cartridge 50C, in the direction of conveyance of a sheet S.

The belt unit 70 includes a drive roller 71, a follower roller 72, a conveyor belt 73 as an example of a belt, and four transfer rollers 74. The conveyor belt 73 is an endless belt having an inside surface and an outside surface.

The drive roller 71 and the follower roller 72 cause the conveyor belt 73 to rotate. The drive roller 71 and the follower roller 72 are located in contact with the inside surface of the conveyor belt 73.

The conveyor belt 73 is a belt that conveys a sheet S across the photosensitive drums 51. In other words, a sheet S is conveyed through between each photosensitive drum 51 and the conveyor belt 73. The outside surface of the conveyor belt 73 contacts the photosensitive drums 51. The transfer rollers 74 are located in contact with the inside surface of the conveyor belt 73, in positions corresponding to the photosensitive drums 51. The conveyor belt 73 is nipped between each transfer roller 74 and the corresponding photosensitive drum 51.

The fixing device 80 includes a heating roller 81 and a pressure roller 82. The heating roller 81 includes a halogen heater 81A. The halogen heater 81A is provided inside the cylindrical body of the heating roller 81. The pressure roller 82 is pressed against the heating roller 81 to nip a sheet S between the pressure roller 82 and the heating roller 81.

In the image forming unit 30, first, the surface of each photosensitive drum 51 is charged by the corresponding charger 52, and then exposed to light by the corresponding LED unit 40. Accordingly, an electrostatic latent image is formed on the photosensitive drum 51. Thereafter, toner is supplied from the development roller to the electrostatic latent image, so that a toner image is formed on the photosensitive drum 51.

Subsequently, a sheet S fed onto the conveyor belt 73 passes through between each photosensitive drum 51 and the corresponding transfer roller 74, so that the toner image formed on the photosensitive drum 51 is transferred onto the sheet S. Thereafter, the toner transferred onto the sheet S is thermally fixed on the sheet S while the sheet S passes through between the heating roller 81 and the pressure roller 82.

The sheet output unit 90 is configured to convey a sheet S outputted from the fixing device 80, toward outside of the main body housing 10. The sheet output unit 90 includes conveyor rollers 91 and an ejection roller 92. A sheet S outputted from the fixing device 80 is conveyed by the conveyor roller 91 to the ejection roller 92, and ejected by the ejection roller 92 onto a sheet output tray 11.

As shown in FIGS. 1 and 2, the image forming unit 30 further includes an optical sensor 100 and a registration sensor RS. The optical sensor 100 is located opposite to the outside surface of the conveyor belt 73 at a position near one end of the conveyor belt 73 at which the drive roller 71 is located, and the registration sensor RS is located opposite to the outside surface of the conveyor belt 73 at a position near the other end of the conveyor belt 73.

The registration sensor RS is a sensor opposed to the outside surface of the conveyor belt 73 to detect positions of patches P formed on the outside surface of the conveyor belt 73. The registration sensor RS includes one light-emitting element and one light-receptive element.

The patches P are test toner images for correction of misregistration and/or density of toner. The patches P include a patch PK for black, a patch PC for cyan, a patch PM for magenta, and a patch PY for yellow. The patches PK, PC, PM and PY are formed on the conveyor belt 73. To correct misregistration, density of toner, or the like, the patches P are transferred from the photosensitive drums 51 onto the conveyor belt 73.

As shown in FIG. 3, the optical sensor 100 is configured to be attachable to a frame F of the laser printer 1. The frame F is a part of the main body housing 10 of the laser printer 1. The optical sensor 100 is located opposite to a surface BS of the conveyor belt 73. The optical sensor 100 is a sensor configured to detect a position and a density of a patch P formed on the surface BS of the conveyor belt 73. Specifically, to test the position and the density of toner to be supplied from the photosensitive drums 51, a controller of the laser printer 1 causes the image forming unit 30 to form patches P on the surface BS of the conveyor belt 73 for detection, as shown in FIG. 2. The optical sensor 100 is configured to detect intensities of a specular reflection component and a diffuse reflection component of light reflected off a patch-formed area that is an area of the surface BS of the conveyor belt 73 in which a patch P is formed, and to detect intensities of a specular reflection component and a diffuse reflection component of light reflected off a no-patch area that is an area of the surface BS of the conveyor belt 73 in which no patch P is formed. The controller determines the position and the density of each patch P, based on the detection results of the optical sensor 100.

The surface BS of the conveyor belt 73 and the patch P of toner are examples of a sensing object. Although the sensing object in this example is the patch P of toner, formed by adhering toner to the surface BS of the conveyor belt 73, the sensing object is not limited to the patch P of toner and may be a mark on the surface BS of the conveyor belt 73.

The optical sensor 100 comprises a substrate 110, a light-emitting element 120, a first light-receptive element 130, a second light-receptive element 140, a lens member 150, a holder 160, and a substrate retainer 170. The first light-receptive element 130 and the second light-receptive element 140 are examples of a light-receptive element.

As shown in FIGS. 4 and 5, the substrate 110 is a plate-shaped member approximately having a shape of a rectangular parallelepiped. Specifically, the substrate 110 has two opposite surfaces: a front surface 110A and a back surface 110B, each formed approximately in a rectangular shape with a length (longer dimension) and a width (shorter dimension). The front surface 110A is a surface facing to the conveyor belt 73 (i.e., to patches P formed on the surface BS of the conveyor belt 73) when the optical sensor 100 is attached to the frame F. The back surface 110B is a surface facing away from the conveyor belt 73 when the optical sensor 100 is attached to the frame F. In the following description, to designate directions with respect to members assembled in the optical sensor 100, the term “first direction” is used to refer to a lengthwise direction or a direction of the length of the substrate 110, the term “second direction” is used to refer to a widthwise direction or a direction of the width of the substrate 110, and the term “third direction” is used to refer to a direction of the thickness (shortest dimension) of the substrate 110. The second direction is an example of a direction nonparallel to the first direction. In the illustrative, non-limiting embodiment described below, the second direction is perpendicular to the first direction. The third direction is perpendicular to the first direction and to the second direction.

The substrate 110 is located between the holder 160 and the substrate retainer 170. The front surface 110A of the substrate 110 facing in one of two opposite directions parallel to the third direction is in contact with the holder 160, and the back surface 110B of the substrate 110 facing in the other of the two opposite directions parallel to the third direction is in contact with the substrate retainer 170.

The light-emitting element 120 has a function of emitting light. The light-emitting element 120 is, for example, an LED. The light-emitting element 120 is fixed to the back surface 110B of the substrate 110. To be more specific, the light-emitting element 120 is fixed to the back surface 110B by soldering. Part of the light-emitting element 120 is disposed in a third hole 113 which will be described later.

The first light-receptive element 130 and the second light-receptive element 140 are, in this example, fixed to the back surface 110B of the substrate 110. To be more specific, the first light-receptive element 130 is fixed to the back surface 110B by soldering, and part of the first light-receptive element 130 is disposed in a first hole 111 which will be described later. Similarly, the second light-receptive element 140 is fixed to the back surface 110B by soldering, and part of the second light-receptive element 140 is disposed in a second hole 112 which will be described later.

As shown in FIG. 3, the light-receptive element (each of the first light-receptive element 130 and the second light-receptive element 140) receives reflected light emitted from the light-emitting element 120, reflected off the patch P and traveling into the through hole (the first hole 111 and the second hole 112 which will be described later). The first light-receptive element 130 and the second light-receptive element 140 are each configured, for example, as a photodiode having sensitivity to light with a specific range of wavelengths including a wavelength of light emitted from the light-emitting element 120.

The first light-receptive element 130 is located in a position at which a specular reflection component of light reflected off the patch P arrives, i.e., such a position that the directions of incident light and reflected light make equal angles with a line perpendicular to the surface at that position. Locating the first light-receptive element 130 in such a position makes the first light-receptive element 130 capable of receiving a specular reflection component of reflected light emitted from the light-emitting element 120 and reflected off the patch P.

The second light-receptive element 140 is located in a position at which a diffuse reflection component of the light reflected off the patch P arrives, i.e., such a position that a component, other than the specular reflection component, of reflected light emitted from the light-emitting element 120 and reflected off the patch P strikes that position of the surface. Locating the second light-receptive element 140 in such a position makes the second light-receptive element 140 capable of receiving a diffuse reflection component of reflected light emitted from the light-emitting element 120 and reflected off the patch P.

The light-emitting element 120, the first light-receptive element 130 and the second light-receptive element 140 are located apart from one another in directions parallel to the first direction. The light-emitting element 120 is located between the first light-receptive element 130 and the second light-receptive element 140. The first light-receptive element 130 is located at a distance from the light-emitting element 120 in one direction parallel to the first direction. The second light-receptive element 140 is located at a distance from the light-emitting element 120 in the other direction (opposite to the one direction in which the first light-receptive element 130 is distanced from the light-emitting element 120) parallel to the first direction. The distance of the first light-receptive element 130 from the light-emitting element 120 is shorter than the distance of the second light-receptive element 140 from the light-emitting element 120. In other words, the first light-receptive element 130 is closer than the second light-receptive element 140 to the light-emitting element 120; the second light-receptive element 140 is farther than the first light-receptive element 130 from the light-emitting element 120.

The substrate 110 has a first hole 111, a second hole 112, a third hole 113, a fourth hole 114, and a fifth hole 115. The first hole 111, the second hole 112, the third hole 113, the fourth hole 114, and the fifth hole 115 are located apart from one another in directions parallel to the first direction. The first hole 111 and the second hole 112 are examples of a through hole piercing through the front surface 110A and the back surface 110B.

The first hole 111 is located between the third hole 113 and the fourth hole 114. The fourth hole 114 is located at a distance from the first hole 111 in one direction parallel to the first direction. The third hole 113 is located at a distance from the first hole 111 in the other direction (opposite to the one direction in which the fourth hole 114 is distanced from the first hole 111) parallel to the first direction. The first hole 111 is a hole corresponding to the first light-receptive element 130. The first hole 111 has a shape of a letter T, and comprises a first portion 111A extending parallel to the first direction and a second portion 111B extending parallel to the second direction. The first portion 111A extends through the front and back surfaces 110A, 110B from a position at which the first light-receptive element 130 is fixed toward a position at which the light-emitting element 120 is fixed. The first portion 111A is a portion into which a specular reflection component of light reflected off a patch P travels. The second portion 111B has a middle part connected to an end of the first portion 111A. The second portion 111B is a portion in which a first leg W11 is disposed. Details on the first leg W11 will be described below.

The second hole 112 is located between the third hole 113 and the fifth hole 115. The third hole 113 is located at a distance from the second hole 112 in one direction parallel to the first direction. The fifth hole 115 is located at a distance from the second hole 112 in the other direction (opposite to the one direction in which the third hole 113 is distanced from the second hole 112) parallel to the first direction. The second hole 112 is a hole corresponding to the second light-receptive element 140. The second hole 112 has a shape of a letter T, and comprises a third portion 112A extending parallel the first direction and a fourth portion 112B extending parallel to the second direction. The third portion 112A extends through the front and back surfaces 110A, 110B from a position at which the second light-receptive element 140 is fixed toward a position at which the light-emitting element 120 is fixed. The third portion 112A is a portion into which a diffuse reflection component of light reflected off a patch P travels. The fourth portion 112B has a middle part connected to an end of the third portion 112A. The fourth portion 112B is a portion in which a second leg W21 is disposed. Details of the second leg W21 will be described below.

The third hole 113 is located in the middle, lengthwise, of the substrate 110. That is, the third hole 113 is equally distanced from two opposite ends of the substrate 110 facing away from each other in directions parallel to the first direction. The third hole 113 is located between the first hole 111 and the second hole 112. The first hole 111 is located at a distance from the third hole 113 in one direction parallel to the first direction. The second hole 112 is located at a distance from the third hole 113 in the other direction (opposite to the one direction in which the first hole 111 is distanced from the third hole 113) parallel to the first direction. The third hole 113 is another through hole piercing through the front surface 110A and the back surface 110B, through which light emitted from the light-emitting element 120 travels.

The fourth hole 114 and the fifth hole 115 are each formed in a round shape to locate the substrate 110 in place. Specifically, a first locating boss 166 and a second locating boss 167 (which will be described later) of the holder 160 are fitted in the fourth hole 114 and the fifth hole 115, respectively, whereby the substrate 110 is located in place relative to the holder 160 in directions parallel to the first direction and in directions parallel to the second direction. The fourth hole 114 is a circular hole, and the fifth hole 115 is an oval hole elongate in the first direction.

The lens member 150 is made of optically transparent plastic. The lens member 150 is located between the frame F and the substrate 110. The lens member 150 has a first surface 150A facing to the frame F, and a second surface 150B facing to the substrate 110. The first surface 150A in this example is a flat surface. The lens member 150 comprises a first optical surface 151, a second optical surface 152, a third optical surface 153, a frame-side optical surface 154, a protrusion 155, a third hook 156, a sixth hole 157, a seventh hole 158 (see also FIG. 4). The first optical surface 151, the second optical surface 152, the third optical surface 153 and the frame-side optical surface 154 are examples of an optical surface of the lens member 150.

The frame-side optical surface 154 is a flat optical surface formed in the first surface 150A. The frame-side optical surface 154 allows light emitted from the light-emitting element 120, a specular reflection component of light reflected off a patch P, and a diffuse reflection component of the light reflected off the patch P to travel therethrough.

The protrusion 155 protrudes from the first surface 150A. In this example, four protrusions 155 are provided and arranged around the frame-side optical surface 154. When the optical sensor 100 is attached to the frame F, the protrusions 155 protrude toward the frame F and contact the frame F, and the frame-side optical surface 154 is kept out of contact with the frame F.

The second surface 150B is an opposite surface facing away from the first surface 150A. The second surface 150B is a surface at least part of which includes a convex optical surface. That is, the lens member 150 has a first surface 150A that is a flat surface facing to the frame F, and a second surface 150B that is a surface facing to the substrate 110 and including a convex optical surface. The second surface 150B includes, as optical surfaces, a first optical surface 151, a second optical surface 152 and a third optical surface 153. Each of the first optical surface 151, the second optical surface 152 and the third optical surface 153 is a curved optical surface, having a convex shape, formed in the second surface 150B. The optical surface of the second surface 150B has a radius of curvature smaller than a radius of curvature of the first surface 150A; thus, the second surface 150B makes the lens member 150 to have positive power. Accordingly, the lens member 150 is a lens having a positive power with the first surface 150A facing to the frame F and the second surface 150B facing to the substrate 110 such that the radius of curvature of the first surface 150A is larger than the radius of curvature of the second surface 150B.

The first optical surface 151 is an optical surface through which light emitted from the light-emitting element 120 travels. The first optical surface 151 refracts the light emitted from the light-emitting element 120.

The second optical surface 152 is an optical surface through which a specular reflection component of light reflected off a patch P travels. The second optical surface 152 refracts the specular reflection component of the light reflected off the patch P.

The third optical surface 153 is an optical surface through which a diffuse reflection component of the light reflected off the patch P travels. The third optical surface 153 refracts the diffuse reflection component of the light reflected off the patch P.

In other words, the second surface 150B includes a first optical surface 151 that refracts light emitted from the light-emitting element 120, a second optical surface 152 that refracts a specular reflection component of light reflected off the sensing object, and a third optical surface 153 that refracts a diffuse reflection component of the light reflected off the sensing object.

The third hook 156 is provided on both ends of the lens member 150 facing away from each other in the directions parallel to the first direction. In other words, two third hooks 156 are provided one on each of the ends of the lens member 150. The third hooks 156 are portions engageable with the holder 160. Each third hook 156 is configured such that when the lens member 150 is attached to the holder 160, the third hook 156 extends into the holder 160. The third hook 156 has two opposite surfaces facing away from each other in opposite directions parallel to the first direction (i.e., perpendicular to a direction of extension of the third hook 156), and a hook hole 156A that is a through hole piercing through the two opposite surfaces. The hook hole 156A is a hole in which a holder lug 168 which will be described later is engageable. When two holder lugs 168 are put in the corresponding hook holes 156A, the lens member 150 is engaged with the holder 160, so that the lens member 150 is prevented from getting detached from the holder 160.

The sixth hole 157 is a circular hole. The seventh hole 158 is an oval hole elongate in the first direction. The sixth hole 157 and the seventh hole 158 serve to locate the lens member 150 in place. Specifically, the sixth hole 157 is a hole in which the first locating boss 166 (which will be described later) of the holder 160 is fitted. The seventh hole 158 is a hole in which the second locating boss 167 (which will be described later) of the holder 160 is fitted. Accordingly, the lens member 150 is located in place relative to the holder 160 in directions parallel to the first direction and in directions parallel to the second direction.

The holder 160 is a plastic member by which the substrate 110 is held. When the optical sensor 100 is attached frame F, the holder 160 is located between the frame F and the substrate 110 (see FIG. 3). The holder 160 as attached to the substrate 110 is located over the front surface 110A of the substrate 110 whereby the light-emitting element 120, the first light-receptive element 130 and the second light-receptive element 140 are covered by the holder 160. The holder 160 holds and fixes the lens member 150 located between the frame F and the holder 160.

The holder 160 comprises a holder body 161, a locating protrusion 161T, an emitted-light path hole 162, a first reflected-light path hole 163, a second reflected-light path hole 164, a first hook 165, a first locating boss 166, a second locating boss 167, a holder lug 168, a second-hook engageable portion 169, a first light-shielding wall W1, and a second light-shielding wall W2.

The locating protrusion 161T protrudes from the holder body 161. The locating protrusion 161T is configured such that when the lens member 150 is attached to the holder 160, the locating protrusion 161T protruding toward the lens member 150 contacts the second surface 150B of the lens member 150 (see FIG. 6). The locating protrusion 161T in contact with the second surface 150B serves to locate the lens member 150 in place relative to the holder 160 in directions parallel to the third direction.

The emitted-light path hole 162 is located in the middle, lengthwise, of the holder 160. That is, the emitted-light path hole 162 is equally distanced from two opposite ends of the holder 160 facing away from each other in directions parallel to the first direction. The emitted-light path hole 162 is a through hole piercing through two opposite surfaces of the holder 160 facing away from each other in directions parallel to the third direction. The emitted-light path hole 162 has a circular shape. Light emitted from the light-emitting element 120 travels through the emitted-light path hole 162.

The first reflected-light path hole 163 and the second reflected-light path hole 164 are through holes piercing through two opposite surfaces of the holder 160 facing away from each other in directions parallel to the third direction. The first reflected-light path hole 163 is located at a distance from the emitted-light path hole 162 in one direction parallel to the first direction. The second reflected-light path hole 164 is located at a distance from the emitted-light path hole 162 in the other direction (opposite to the one direction in which the first reflected-light path hole 163 is distanced from the emitted-light path hole 162) parallel to the first direction. The specular reflection component of reflected light emitted from the light-emitting element 120 and reflected off a patch P travels through the first reflected-light path hole 163 to the first light-receptive element 130. The diffuse reflection component of the reflected light emitted from the light-emitting element 120 and reflected off the patch P travels through the second reflected-light path hole 164 to the second light-receptive element 140.

The first hook 165 is a portion protruding from the holder body 161 and engaging with the frame F. The first hook 165 has a shape of a letter L with a base portion protruding from the holder body 161 in a direction parallel to the third direction, and an end portion extending in a direction (in this example, “the other direction” mentioned above) parallel to the first direction. In this example, two first hooks 165 are provided in positions apart from each other in the first direction. The end portions of these two first hooks 165 extend in the same direction parallel to the first direction.

As shown in FIGS. 4 and 5, each of the first locating boss 166 and the second locating boss 167 has a shape of a solid circular cylinder of which an axis is oriented parallel to the third direction. The first locating boss 166 and the second locating boss 167 protrude from the holder body 161 in both of two opposite directions parallel to the third direction. The length of protrusion of the second locating boss 167 from a surface of the holder body 161 facing toward the substrate 110 is longer than the length of protrusion of the first locating boss 166 from the surface of the holder body 161 facing toward the substrate 110. The first locating boss 166 and the second locating boss 167 are provided in positions apart from each other in the first direction.

The first locating boss 166 is fitted in the sixth hole 157 of the lens member 150, through the fourth hole 114 of the substrate 110, and in a first locating guideway 173 (which will be described later) of the substrate retainer 170, so that the lens member 150, the substrate 110, the holder 160, and the substrate retainer 170 are located in place in directions parallel to the first direction and in directions parallel to the second direction. The second locating boss 167 is fitted in the seventh hole 158 of the lens member 150, through the fifth hole 115 of the substrate 110, and in a second locating guideway 174 (which will be described later) of the substrate retainer 170, so that the lens member 150, the substrate 110, the holder 160, and the substrate retainer 170 are located in place in directions parallel to the first direction and in directions parallel to the second direction.

The holder lug 168 is a projection formed on the holder body 161. Two holder lugs 168 are provided in this example in positions apart from each other in the first direction, specifically, one being provided near the first locating boss 166, between the first hook 165 and the first locating boss 166 located apart from each other in directions parallel to the first direction, and the other being provided near the second locating boss 167, between the first hook 165 and the second locating boss 167 located apart from each other in directions parallel to the first direction. Each holder lug 168 protrudes in a direction parallel to the first direction toward the corresponding first hook 165. The holder lug 168 is engageable with the corresponding hook hole 156A of the lens member 150. When the lens member 150 is attached to the holder 160, the dimension of the hook hole 156A in the third direction (i.e., the direction of extension of the third hook 156, see FIG. 6) is greater than the dimension of the holder lug 168 in third direction, whereby a clearance is left between the hook hole 156A and the holder lug 168 engaged with the hook hole 156A. It is understood that the holder lug 168 and the hook 156, as engaged with each other with clearance left therebetween, thus do not serve to locate the lens member 150 in place relative to the holder 160 in directions parallel to the third direction.

The second-hook engageable portion 169 is located at two ends of the holder 160 which are located apart from each other in directions parallel to the first direction. The second-hook engageable portion 169 is a portion with which a second hook 172 of the substrate retainer 170 (which will be described later) is engageable.

The first light-shielding wall W1 is located between the light-emitting element 120 and the first light-receptive element 130. The first light-shielding wall W1 is a wall that blocks out and prevents light traveling from the light-emitting element 120 in directions other than directions in which light travels through the emitted-light path hole 162 of the holder 160 from reaching the first light-receptive element 130. The first light-shielding wall W1 has two opposite surfaces facing away from each other in directions parallel to the first direction: one of the surfaces faces the light-emitting element 120 and the other faces the first light-receptive element 130. The first light-shielding wall W1 includes a first leg W11 that is disposed in the first hole 111 of the substrate 110.

The first leg W11 is a portion of the first light-shielding wall W1, which is located inside the first hole 111. In this example, the first leg W11 is fitted in the second portion 111B of the first hole 111.

The first light-shielding wall W1 has a groove MZ formed in an opposite surface W12 thereof facing to the light-emitting element 120 (see also FIG. 7). The groove MZ is a notch formed in a shape of a letter V as viewed from a direction parallel to the third direction. The groove MZ extends parallel to an optical axis of the light-emitting element 120, that is, parallel to the third direction.

The second light-shielding wall W2 is located between the light-emitting element 120 and the second light-receptive element 140. The second light-shielding wall W2 is a wall that blocks out and prevents light traveling from the light-emitting element 120 in directions other than directions in which light travels through the emitted-light path hole 162 of the holder 160 from reaching the second light-receptive element 140. The second light-shielding wall W2 has two opposite surfaces facing away from each other in directions parallel to the first direction: one of the surfaces faces the light-emitting element 120 and the other faces the second light-receptive element 140. The second light-shielding wall W2 includes a second leg W21 that is disposed in the second hole 112 of the substrate 110.

The second leg W21 is a portion of the second light-shielding wall W1, which is located inside the second hole 112. In this example, the second leg W21 is fitted in the fourth portion 112B of the second hole 112.

The retainer body 171 is a member by which the substrate 110 is held and fixed between the holder 160 and the substrate retainer 170. The substrate retainer 170 comprises a retainer body 171, a second hook 172, a first locating guideway 173, a second locating guideway 174, a first elastic portion 175, and a second elastic portion 176.

The second hook 172 protrudes from the retainer body 171. The second hook 172 is a hook engageable with the holder 160. Two second hooks 172 are provided on the substrate retainer 170, one on each of the ends of the substrate retainer 170 facing away from each other in directions parallel to the first direction. The second hooks 172 protrude from the substrate retainer 170 in one and the same direction that is one of two opposite directions parallel to the third direction. Each second hook 172 is engaged with a corresponding second-hook engageable portion 169. The both second hooks 172 are engaged with the respective second-hook engageable portions 169, whereby the substrate retainer 170 is fixed to the holder 160.

The first locating guideway 173 and the second locating guideway 174 are grooves provided in the retainer body 171. The first locating boss 166 of the holder 160 is slid into the first locating guideway 173. The second locating boss of the holder 160 is slid into the second locating guideway. Accordingly, the substrate retainer 170 is located in place relative to the holder 160 in directions parallel to the first direction and in directions parallel to the second directions.

The first elastic portion 175 and the second elastic portion 176 are portions that are thinner and less rigid than other portions of the substrate retainer 170.

Next, referring to FIGS. 3 to 5, a method for assembling the optical sensor 100 and a method for attaching the optical sensor 100 to the frame F will be described below.

To assemble the optical sensor 100, first, as shown in FIG. 4, the lens member 150 is fitted on the holder 160. To this end, the first locating boss 166 of the holder 160 is inserted into the sixth hole 157 of the lens member 150, and the second locating boss 167 of the holder 160 is inserted into the seventh hole 158 of the lens member 150. Then, as shown in FIG. 3, the holder lugs 168 of the holder 160 are engaged with the hook holes 156A of the lens member 150, so that the lens member 150 becomes less likely to get detached from the holder 160. In this state where the lens member 150 is attached to the holder 160, a clearance is left between the hook hole 156A and the holder lug 168 engaged with the hook hole 168; therefore, no stress is imposed on the lens 150 and the holder 160.

Next, the substrate 110 is interposed between the holder 160 and the substrate retainer 170, and the substrate retainer 170 is attached to the holder 160. In this process, the first locating boss 166 of the holder 160 is inserted through the fourth hole 114 of the substrate 100 and put into the first locating guideway 173 of the substrate retainer 170, and the second locating boss 167 of the holder 160 is inserted through the fifth hole 115 of the substrate 100 and put into the second locating guideway 174 of the substrate retainer 170. Then, the second hooks 172 of the substrate retainer 170 are engaged with the second-hook engageable portions 169 of the holder 160. When the second hooks 172 are engaged with the second-hook engageable portions 169, the first elastic portion 175 and the second elastic portion 176 are bent or warped. Accordingly, the retainer body 171 presses the substrate 110 against the holder 160 by the elasticity of the first elastic portion 175 and the second elastic portion 176. In this way, when the second hooks 172 are engaged with the holder 160, the retainer body 171 presses the substrate 110 against the holder 160.

Subsequently, to attach the optical sensor 100 to the frame F, the first hooks 165 are inserted into frame holes FH in the frame F, respectively; thereafter, the whole optical sensor 100 is slid in the direction in which the end portions of the first hooks 165 extend (i.e., one of two opposite directions parallel to the first direction). Accordingly, the two first hooks 165 are engaged with the frames F, whereby the optical sensor 100 is made less likely to be detached from the frame F.

To be more specific, once the first hooks 165 have been engaged with the frame F, the first hooks 165 elastically deform or bend in one direction (away from the frame F) parallel to the third direction in such a manner that the L shape of each first hook 165 slightly spreads out resiliently. Elasticity of the first hooks 165 thus deformed causes the holder body 161 to be pulled toward the frame F. Accordingly, when the first hooks 165 are engaged with the frame F, the holder body 161 presses the lens member 150 against the frame F.

According to the illustrative embodiment as described above, the following advantageous effects can be achieved.

Since the light-receptive element 130 and the light-receptive element 140 are fixed to the back surface 110B of the substrate 110, the optical sensor 100 can be configured to have a reduced thickness (dimension in the third direction). In such configuration, typically, as shown in FIG. 8B, a substrate 110J should necessarily have through holes 111J, 112J into which reflected light emitted from the light-emitting element 120 and reflected off a patch travels. In the illustrated example, however, part of light to be received by the light-receptive elements 130, 140 would possibly be interrupted by the edges of the through holes 111J, 112J as shown in FIG. 8B, with the result that the quantity of light would disadvantageously be reduced.

In contrast, the optical sensor 100 of the above-described embodiment is configured such that the through hole, i.e., each of the first hole 111 and the first hole 112, of the substrate 110 extends from a position at which the light-receptive element (the first light-receptive element 130 or the second light-receptive element 140) is fixed toward a position at which the light-emitting element 120 is fixed. Therefore, light to be received by the light-receptive elements 130, 140 is less likely to be interrupted by the edges of the first hole 111 and the second hole 112. Accordingly, undesirable reduction in quantity of light traveling into the first hole 111 and the second hole 112 to be received by the first light-receptive element 130 and the second light-receptive element 140 can be restrained.

In addition, the holder 160 of the optical sensor 100 comprises the first light-shielding wall W1 located between the light-emitting element 120 and the first light-receptive element 130, and the second light-shielding wall W2 located between the light-emitting element 120 and the second light-receptive element 130, and the first groove MZ is formed in the opposite surface W12 of the first light-shielding wall W1, as shown in FIG. 9. Supposing that the first light-shielding wall W1 has no groove formed therein, as shown in FIG. 10, light emitted from the light-emitting element 120 would possibly be reflected off the opposite surface W12 of the first light-shielding wall W1 and undesirably reach the second light-receptive element 140.

In contrast, since the optical sensor 100 of the above-described embodiment is configured, as shown in FIG. 9, such that the first light-shielding wall W1 of the holder 160 has the groove MZ formed in the opposite surface W12, light emitted from the light-emitting element 120 is reflected off the groove MZ in directions different from a direction in which light emitted from the light-emitting element 120 travels toward a patch P. Accordingly, the second light-receptive element 140 is restrained from receiving a reflection component of such light reflected off a patch P as would be derived from light emitted from the light-emitting element 120, reflected off the opposite surface W12 and directed to the patch P. As a result, the second light-receptive element 140 can provide an improved readout with high accuracy and precision.

Since the light-emitting element 120 is fixed to the back surface 110B of the substrate 110, the both of the light-emitting element 120 and the light-receptive element (including the first light-receptive element 130 and the second light-receptive element 140) are located on the back side of the substrate 110. Therefore, the optical sensor 100 can be assembled with increased ease.

As the first hooks 165 are engaged with the frame F, the holder body 161 of the optical sensor 100 presses the lens member 150 against the frame F. To be more specific, when the holder 160 is attached to the frame F, the first hooks 165 elastically deform or bend in a direction parallel to the third direction in such a manner that the L shape of each first hook 165 spreads out resiliently; therefore, elasticity of the first hooks 165 thus deformed pulls the holder body 161 toward the frame F. Accordingly, the lens member 150 is pressed against the frame F. Since the lens member 150 is pressed against the frame F and fixed to the frame F, the distances from the light-emitting element 120, the first light-receptive element 130, the second light-receptive element 140, and the lens member 150 to a patch P can be controlled precisely with minimal errors. As a result, the light-emitting element 120, the first light-receptive element 130, the second light-receptive element 140, and the lens member 150 can be located precisely within tolerances or permissible limits of errors in distance to the patch P; therefore, the accuracy and precision of measurement of location and density of the patch P can be improved.

As the second hooks 172 are engaged with the second-hook engageable portion 169 of the holder 160, the first elastic portion 175 and a second elastic portion 176 of the retainer body 171 are elastically bent or warped; therefore, elasticity of the first elastic portion 175 and the second elastic portion 176 thus warped causes the retainer body 171 to press the substrate 110 against the holder 160. Since the substrate 110 is pressed against the holder 160 and fixed to the holder 160, the distances from the light-emitting element 120, the first light-receptive element 130, the second light-receptive element 140, and the lens member 150 to a patch P can be controlled precisely with minimal errors. As a result, the light-emitting element 120, the first light-receptive element 130, the second light-receptive element 140, and the lens member 150 can be located precisely within tolerances or permissible limits of errors in distance to the patch P; therefore, the accuracy and precision of measurement of location and density of the patch P can be improved.

The locating protrusion 161T of the holder 160 is configured such that when the lens member 150 is attached to the holder 160, the locating protrusion protruding toward the lens member 150 contacts the lens member 150. With this locating protrusion 161T in contact with the lens member 150, the lens member 150 is located in place relative to the holder 160, so that a high positioning accuracy of the lens member 150 can be achieved.

The protrusion 155 of the lens member 150 is configured such that when the optical sensor 100 is attached to the frame F, the protrusion 155 protruding toward the frame F contacts the frame F and the frame-side optical surface 154 is kept out of contact with the frame F. Accordingly, the protrusion 155 in contact with the frame F serves to restrain the frame-side optical surface 154 from being displaced relative to the frame F, and the frame-side optical surface 154 kept out of contact with the frame F is restrained from suffering damage by the contact.

The lens member 150 comprises the third hook 156 engaged with the holder 160. Therefore, the lens member 150 is rendered less likely to be detached from the holder 160.

When the lens member 150 is attached to the holder 160, a clearance in the third direction (the direction of extension of the third hook 156 extending into the holder 156, that is, the direction of thickness of the substrate 110 held by the holder 160) is left between the hook hole 156A and the holder lug 168 engaged with the hook hole 156A. With this configuration, the holder lug 168 engaged with the hook hole 156A with a clearance in the third direction serves to keep the lens member 150 from being detached from the holder 160, without obstructing proper positioning of the lens member 150 on the holder 160. In addition, presence of a clearance between the hook hole 156A and the holder lug 168 engaged therewith serves to restrain the lens member 150 from deformation as would otherwise be caused by the engagement of the holder lug 168 in the hook hole 156A.

The lens member 150 has the first surface 150A facing to the frame F and the second surface 150B facing to the substrate 110, and the frame-side optical surface 154 that is a flat surface is provided in the first surface 150A. With this lens configuration of which the first surface 150A facing to the frame F is less convex, the operation of attaching the optical sensor 100 to the frame F would be unlikely to damage the frame-side optical surface 154.

The lens member 150 is configured such that a radius of curvature of the first surface 150A facing to the frame F is larger than a radius of curvature of the second surface 150B facing to the substrate 110. With this lens configuration, the operation of attaching the optical sensor 100 to the frame F is unlikely to damage the optical surface of the lens member 150.

While the invention has been described in conjunction with various example structures outlined above and illustrated in the figures, various alternatives, modifications, variations, improvements, and/or substantial equivalents, whether known or that may be presently unforeseen, may become apparent to those having at least ordinary skill in the art. Accordingly, the example embodiments of the disclosure, as set forth above, are intended to be illustrative of the invention, and not limiting the invention. Various changes may be made without departing from the spirit and scope of the disclosure. Therefore, the disclosure is intended to embrace all known or later developed alternatives, modifications, variations, improvements, and/or substantial equivalents. Some specific examples of potential alternatives, modifications, or variations in the described invention are provided below:

An alternative example of the optical sensor will be described below. In the following description, the members having the same or substantially the same structural features will be designated by the same reference characters, and a detailed explanation thereof will be omitted.

Referring to FIG. 11, an optical sensor 200 as a second example is different from the first example described above in that the first light-receptive element 130 and the second light-receptive element 140 are located on a substrate's front surface (see also FIGS. 12 and 13). Specifically, the optical sensor 200 comprises a substrate 210 and a substrate retainer 270 different in shape from the substrate 110 and the substrate retainer 170 of the first example. The shapes of the lens member 150 and the holder 160 of the optical sensor 200 are the same as those of the first example.

The substrate 210 of the second example has a first hole 211 corresponding to the first light-receptive element 130, and a second hole 212 corresponding to the second light-receptive element 140.

As mentioned above, the first light-receptive element 130 and the second light-receptive element 140 are fixed to the front surface 210A of the substrate 210. Accordingly, the substrate 210 has no such through holes that at least part of the light reflected off a patch P travels inside the through holes. More specifically, the first hole 211 extends straight parallel to the second direction. The first hole 211 is a through hole in which the first leg W11 of the first light-shielding wall W1 is disposed. The second hole 212 extends straight parallel to the second direction. The second hole 212 is a through hole in which the second leg W21 of the second light-shielding wall W2 is disposed.

The substrate retainer 270 of the second example is different from the substrate retainer 170 of the first example in that the former has neither of the first locating guideway nor the second locating guideway as provided in the latter.

In the second example, as well, the lens member 150 can be pressed against and fixed to the frame F, and the substrate 210 can be pressed against and fixed to the holder 160. Therefore, the distances from the light-emitting element 120, the first light-receptive element 130, the second light-receptive element 140, and the lens member 150 to a patch P can be controlled precisely with minimal errors.

In the examples described above, four protrusions 155 are provided on the first surface 150A of the lens member 150; however, the number of protrusions is not limited to four, but may be one, two, three, five, or more.

In the first example, the light-emitting element 120, the first light-receptive element 130, and the second light-receptive element 140 are partially disposed in the corresponding through holes (in the third hole 113, the first hole 111, and the second hole 112, respectively) of the substrate 110; however, each of the light-emitting element 120, the first light-receptive element 130, and the second light-receptive element 140 may be disposed as a whole in the corresponding through hole, or each of the light-emitting element 120, the first light-receptive element 130, and the second light-receptive element 140 may not be disposed inside the corresponding through hole.

In the second example, the first light-receptive element 130 and the second light-receptive element 140 are disposed on the front surface 210A of the substrate 210 without being embedded partially or entirely in the front surface 210; however, each of the first light-receptive element 130 and the second light-receptive element 140 may be embedded, fitted, or placed partially or entirely in a hole(s) or a groove(s) provided in the substrate 210.

In the above-described examples, the lens member 150 is made of optically transparent plastic material; however, the lens member may be made of material, other than plastic, such as glass.

In the above-described examples, the conveyor belt 73 that conveys a sheet S across the photosensitive drums 51 is illustrated as a belt, but this is not a prerequisite. Alternatively, for example, the belt may be an intermediate transfer belt that conveys a toner image transferred thereon by each photosensitive drum in a first transfer process to a position in which the toner image is to be transferred onto a sheet in a second transfer process.

In the above-described examples, the laser printer 1 is illustrated to describe feasible implementation of an image forming apparatus; it is however to be understood that the image forming apparatus may be of any other types, which include a photocopier, a multifunction printer, or the like.

Each element explained above in connection with the embodiments and modified examples may be combined where appropriate for practical implementation.

What is claimed is:

1. An optical sensor configured to detect a sensing object, the optical sensor comprising:
a plate-shaped substrate having a front surface, a back surface and a first hole piercing through the front surface and the back surface;
a light-emitting element that emits light, the light-emitting element being fixed to the substrate; and
a first light-receptive element that receives reflected light emitted from the light-emitting element, reflected off the sensing object and traveling into the first hole, the first light-receptive element being fixed to the back surface of the substrate,
wherein the first hole extends from a position at which the first light-receptive element is fixed toward a position at which the light-emitting element is fixed.

2. The optical sensor according to claim 1, wherein the substrate further has a second hole piercing through the front surface and the back surface,
wherein the optical sensor further comprises a second light-receptive element that receives a diffuse reflection component of light reflected off the sensing object and traveling into the second hole, the second light-receptive element being fixed to the back surface of the substrate, and
wherein the second hole extends from a position at which the second light-receptive element is fixed toward the position at which the light-emitting element is fixed.

3. The optical sensor according to claim 2, further comprising a holder by which the substrate is held, the holder comprising:
an emitted-light path hole through which light emitted from the light-emitting element travels;
a first reflected-light path hole through which light reflected off the sensing object travels to the first light-receptive element; and
a second reflected-light path hole through which light reflected off the sensing object travels to the second light-receptive element.

4. The optical sensor according to claim 3, wherein the holder further comprises:
a first light-shielding wall located between the light-emitting element and the first light-receptive element; and
a second light-shielding wall located between the light-emitting element and the second light-receptive element,
wherein the first light-shielding wall has a groove formed in a surface thereof facing to the light-emitting element.

5. The optical sensor according to claim 4, wherein the groove extends parallel to an optical axis of the light-emitting element.

6. The optical sensor according to claim 4, wherein the first hole has:
a first portion through which a specular reflection component of light reflected off the sensing object travels; and
a second portion connected to the first portion and extending in a direction nonparallel to a direction of extension of the first portion,
wherein the second hole has:
a third portion through which a diffuse reflection component of the light reflected off the sensing object travels; and
a fourth portion connected to the third portion and extending in a direction nonparallel to a direction of extension of the third portion,
wherein the first light-shielding wall includes a first leg disposed in the second portion, and
wherein the second light-shielding wall includes a second leg disposed in the fourth portion.

7. The optical sensor according to claim 1, wherein the light-emitting element is fixed to the back surface of the substrate, and
wherein the substrate has a third hole that is a through hole piercing through the front surface and the back surface, through which light emitted from the light-emitting element travels.

8. The optical sensor according to claim 1, further comprising a holder for holding the substrate, the holder comprising:
an emitted-light path hole through which light emitted from the light-emitting element travels; and
a first reflected-light path hole through which light reflected off the sensing object travels to the first light-receptive element.

9. The optical sensor according to claim 8, wherein the holder further comprises:
a first light-shielding wall located between the light-emitting element and the first light-receptive element,
wherein the first light-shielding wall has a groove formed in a surface thereof facing to the light-emitting element.

10. The optical sensor according to claim 9, wherein the first hole has:
a first portion through which a specular reflection component of light reflected off the sensing object travels; and
a second portion connected to the first portion and extending in a direction nonparallel to a direction of extension of the first portion,
wherein the first light-shielding wall includes a first leg disposed in the second portion.

11. An optical sensor to be attached to a frame of an image forming apparatus and configured to detect a sensing object, the optical sensor comprising:
a substrate;
a light-emitting element that emits light, the light-emitting element being fixed to the substrate;
a light-receptive element that receives reflected light emitted from the light-emitting element and reflected off the sensing object, the light-receptive element being fixed to the substrate;
a holder comprising a holder body and a first hook protruding from the holder body, the first hook being engageable with the frame; and
a lens member located between the frame and the substrate, the lens member having an optical surface through which light emitted from the light-emitting element travels,
wherein when the first hook is engaged with the frame, the holder body presses the lens member against the frame.

12. The optical sensor according to claim 11, further comprising a substrate retainer by which the substrate is held and fixed between the holder and the substrate retainer, the substrate retainer comprising a retainer body and a second hook protruding from the retainer body, the second hook being engageable with the holder,
wherein when the second hook is engaged with the holder, the retainer body presses the substrate against the holder.

13. The optical sensor according to claim 11, wherein the holder further comprises a locating protrusion configured such that when the lens member is attached to the holder, the locating protrusion protruding toward the lens member contacts the lens member.

14. The optical sensor according to claim 11, wherein the lens member comprises a protrusion configured such that when the optical sensor is attached to the frame, the protrusion protruding toward the frame contacts the frame, and the optical surface is kept out of contact with the frame.

15. The optical sensor according to claim 14, wherein the lens member further comprises a third hook engageable with the holder.

16. The optical sensor according to claim 15, wherein the substrate is a plate-shaped member extending in a lengthwise direction,
wherein the third hook is configured such that when the lens member is attached to the holder, the third hook extends into the holder, the third hook having a hook hole that is a through hole piercing through the third hook in the lengthwise direction,
wherein the holder further comprises a holder lug protruding in the lengthwise direction and engageable with the hook hole, and
wherein when the lens member is attached to the holder, a clearance is left between the hook hole and the holder lug engaged with the hook hole in a direction of thickness of the substrate.

17. The optical sensor according to claim 11,
wherein the light-receptive element comprises:
a first light-receptive element that receives a specular reflection component of light reflected off the sensing object; and
a second light-receptive element that receives a diffuse reflection component of the light reflected off the sensing object, and
wherein the substrate comprises:
a first hole corresponding to the first light-receptive element; and
a second hole corresponding to the second light-receptive element.

18. The optical sensor according to claim 17,
wherein the holder further comprises:
a first light-shielding wall located between the light-emitting element and the first light-receptive element; and
a second light-shielding wall located between the light-emitting element and the second light-receptive element, and
wherein the first light-shielding wall has a groove formed in a surface thereof facing to the light-emitting element.

19. The optical sensor according to claim 18, wherein the groove extends parallel to an optical axis of the light-emitting element.

20. The optical sensor according to claim 11, wherein the lens member is a lens having a positive power, and having a first surface facing to the frame and a second surface facing to the substrate, a radius of curvature of the first surface being larger than a radius of curvature of the second surface.
